(19) United States
(12) Patent Application Publication
(10) Pub. No.: US 2006/0206772 A1
(43) Pub. Date: Sep. 14, 2006

(54) Method and apparatus for supporting test pattern generation, and computer product

(75) Inventors: Naoko Karasawa, Kawasaki (JP); Hideaki Konishi, Kawasaki (JP); Yuko Katoh, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/214,849

(22) Filed: Aug. 31, 2005

(30) Foreign Application Priority Data
Mar. 9, 2005 (JP) 2005-066232

(51) Int. Cl. G01R 31/28; G06F 11/00

(52) U.S. Cl. 714/738

(57) ABSTRACT

In an apparatus for supporting test pattern generation, when an acquiring unit acquires connection information of a target circuit to be tested and an untested path, a detecting unit detects paths between all flip-flop cells in the target circuit to create an untested path list. A path extracting unit extracts tested paths and creates a tested path list. A search unit creates a search-result list. A cell extracting unit extracts an untested cell and changes end flags of the untested paths including the untested cell extracted from “0” to “1”. When all end flags in the untested path list are changed to “1”, a correcting unit corrects the connection information, so that a dummy buffer is inserted and connected to a data pin of the untested cell.

### CROSS-REFERENCE TO RELATED APPLICATIONS

This application is based upon and claims the benefit of priority from the prior Japanese Patent Application No.2005-066232, filed on Mar. 9, 2005, the entire contents of which are incorporated herein by reference.

### BACKGROUND OF THE INVENTION

1. Field of the Invention

The present invention relates to a method and apparatus for supporting test pattern generation, and a computer product.

2. Description of the Related Art

Conventionally, in a transition delay test, which is one of delay tests, a test pattern in which rise delay and fall delay are assumed for input/output of a cell, to detect a failure thereof, is generated. Before generating a test pattern for the transition delay test, timing verification in a test mode is performed in a static timing analysis (STA), to confirm that there is no error. In the transition delay test, since a path for propagating a failure is automatically determined by an automatic test-pattern generation (ATPG), it is necessary to verify the timing between synchronous clocks by the STA, so that any path can be activated by the ATPG without causing a problem.

Furthermore, when there is a multi-cycle path or a false path in timing restriction, a setting for excluding such path from a test target. The false path is a path that is not subjected to setup/hold check in the STA, in a circuit to be tested (hereinafter, “target circuit”). Since in the ATPG, a path determined to have no error as a result of the setup/hold check is used, the false path is not subjected to the ATPG.

The multi-cycle path is a path having a clock cycle of two times or more. Since in the ATPG, a path between synchronous clocks is used, the multi-cycle path is not subjected to the ATPG. One example of description of the false path set in a synopsys design constraints (SDC) format is shown below.

```
set_false_path-from CLOCK_NAME_OR_CONCAT_PIN_LIST
    -through CONCAT_PIN_LIST
    -to CLOCK_NAME_OR_CONCAT_PIN_LIST
```

[-from] specifies a start point of a path, which is not subjected to the timing analysis.

[-through] specifies a pin name, through which the path, which is not subjected to the timing analysis, passes without fail.

[-to] specifies the end of the path, which is not subjected to the timing analysis.

Conventionally, a file for specifying a path not to be tested is manually created based on the description in the SDC format. Normally, a cell connected to a data pin in a flip-flop (FF) cell specified by [-to] is specified.

Furthermore, conventionally, clock setting information is extracted from timing constraint information in the STA to set timing information in a transition test pattern. One example of description of test clock information set in the SDC format is shown below.

create_clock-period cycle-waveform [rise fall] clock terminal name

When an error occurs in the STA, timing is adjusted until a timing error is eliminated. However, when the timing cannot be adjusted, it is possible to perform the ATPG by setting the path to be excluded from the test target. In this case, timing error information that could not be settled is extracted from a list of results of the STA, and based on the timing error information, such path is set to be excluded from the test target in the transition delay test. Technologies in which information of the STA is used in the ATPG are disclosed in, for example, Japanese Patent Application Laid-open Nos. 2004-013720, 2003-141206, 2001-297125, and 2003-157297.

In the conventional technologies, however, since a cell (hereinafter, “untested cell”) not to be tested is specified manually, an error is likely to occur. As a result, such a process for specifying the untested cell is required to be repeated for correction, thereby increasing turn around time (TAT). Furthermore, if a path (hereinafter, “untested path”) not to be tested is determined based only on the timing constraint information, a detection rate in the transition delay test decreases. FIG. 1 is a circuit diagram of a target circuit to be tested. In FIG. 1, there are two paths Pa and Pb shown below.

Path Pa: FF1101-Cell 1110-FF1102

Path Pb: FF1101-Cell 1110-FF1103

When the path Pa is the false path, a cell 1110 is set as an untested cell. Even though the false path is only the path Pa, also the path Pb necessarily becomes an untested path due to the cell 1110. Thus, the detection rate decreases.

### SUMMARY OF THE INVENTION

It is an object of the present invention to solve at least the above problems in the conventional technology.

An apparatus for supporting test pattern generation according to one aspect of the present invention includes an acquiring unit that acquires connection information including a netlist of a target circuit to be tested and an untested path that is a path not to be tested; a detecting unit that detects all paths between flip-flop cells in the target circuit based on the connection information; a path extracting unit that extracts a tested path that is a path to be tested, from among the paths detected based on the untested path; and a cell extracting unit that extracts an untested cell that is not to be tested from among cells in the target circuit, based on cells forming the untested path and cells forming the tested path.

A method of supporting test pattern generation according to another aspect of the present invention includes acquiring connection information including a netlist of a target circuit to be tested and an untested path that is a path not to be tested; detecting all paths between flip-flop cells in the target circuit based on the connection information; extracting a tested path that is a path to be tested, from among the paths detected based on the untested path; and extracting an untested cell that is not to be tested from among cells in the target circuit, based on cells forming the untested path and cells forming the tested path.

A computer-readable recording medium according to still another aspect of the present invention stores a computer program for realizing a method of supporting test pattern generation according to the above aspect.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a circuit diagram of a target circuit to be tested;

FIG. 2 is a schematic of a hardware configuration of an apparatus for supporting test pattern generation according to embodiments of the present invention;

FIG. 3 is a circuit diagram of a target circuit;

FIG. 4 is a block diagram of a functional configuration of the apparatus shown in FIG. 2;

FIG. 5 is a table of an untested path list;

FIG. 6 a table of a tested path list;

FIG. 7 a table of a search-result list;

FIG. 8 a table of the untested path list after changing an end flag;

FIG. 9 a table of a search-result list after changing the end flag shown in FIG. 8;

FIG. 10 is a circuit diagram of the target circuit in which a dummy buffer is inserted; and

FIG. 11 is a flowchart of a test-pattern-generation supporting process according to the embodiments.

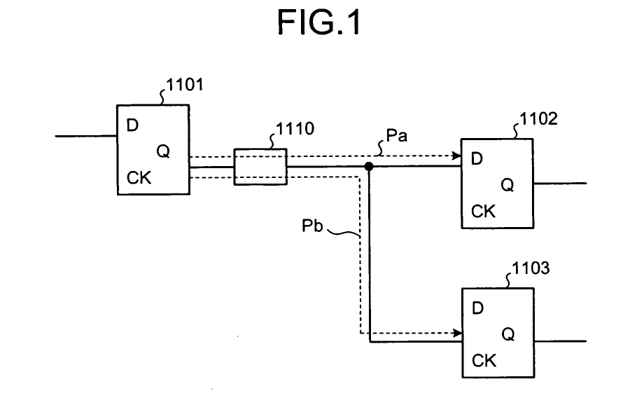

### DETAILED DESCRIPTION OF THE PREFERRED EMBODIMENTS

Exemplary embodiments of the present invention will be explained in detail below with reference to the accompanying drawings.

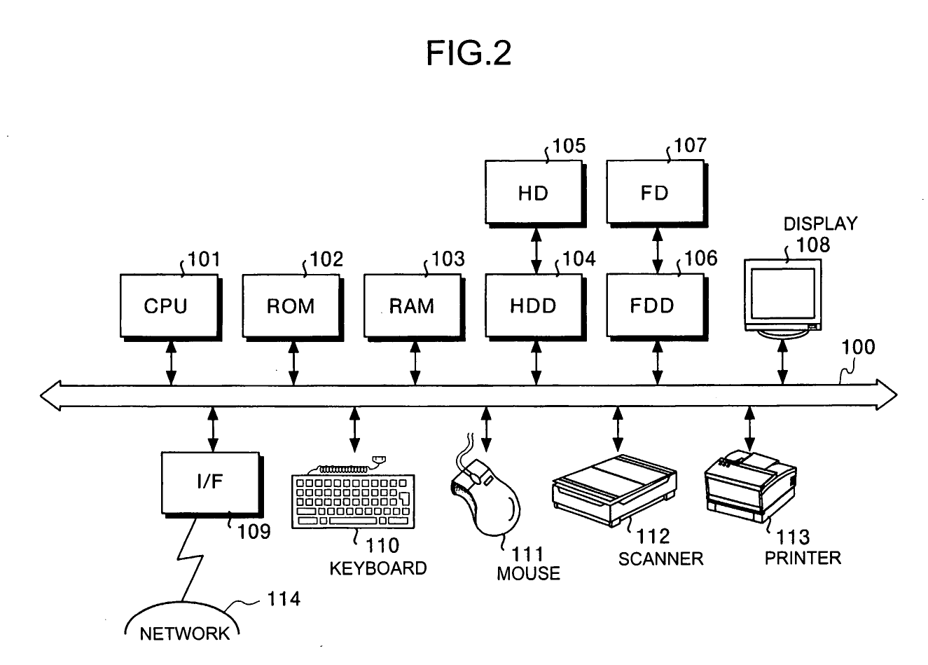

FIG. 2 is a block diagram of a hardware configuration of an apparatus for supporting test pattern generation according to embodiments of the present invention. As shown in FIG. 2, the apparatus includes a central processing unit (CPU) 101, a read only memory (ROM) 102, a random access memory (RAM) 103, a hard disk drive (HDD) 104, a hard disk (HD) 105, a flexible disk drive (FDD) 106, a flexible disk (FD) 107 as a removable recording medium, a display 108, an interface (I/F) 109, a keyboard 110, a mouse 111, a scanner 112, and a printer 113. Each of components is connected through a bus 100.

The CPU 101 controls a whole of the apparatus. The ROM 102 stores a computer program such as a boot program. The RAM 103 is used as a work area of the CPU 101. The HDD 104 controls read/write of data from/to the HD 105 in accordance with the control of the CPU 101. The HD 105 stores data that is written in accordance with the control of the HDD 104.

The FDD 106 controls read/write of data from/to the FD 107 in accordance with the control of the CPU 101. The FD 107 stores data that is written by a control of the FDD 106 and lets the apparatus read the data stored in the FD 107.

Apart from the FD 107, a compact disc-read only memory (CD-ROM), a compact disc-readable (CD-R), a compact disc-rewritable (CD-RW), a magneto optical disc (MO), a digital versatile disc (DVD), and a memory card may also be used as the removable recording medium. The display 108 displays a curser, an icon, a tool box as well as data such as documents, images, and functional information. A cathode ray tube (CRT), a thin film transistor (TFT) liquid crystal display, or a plasma display can be used as the display 108.

The I/F 109 is connected to a network 114 such as the Internet through a communication line and is connected to other devices through the network 114. The I/F 109 controls the network 114 and an internal interface to control input/output of data to/from external devices. A modem or a local area network (LAN) adapter can be used as the I/F 109.

The keyboard 110 includes keys for inputting characters, numbers, and various instructions, and is used to input data. A touch panel input pad or a numerical key pad may also be used as the keyboard 110. The mouse 111 is used to shift the curser, select a range, shift windows, and change sizes of the windows on a display. A track ball or a joy stick may be used as a pointing device if functions similar to those of the mouse 111 are provided.

The scanner 112 optically captures an image and inputs image data to the apparatus. The scanner 112 may be provided with an optical character read (OCR) function. The printer 113 prints the image data and document data. For example, a laser printer or an inkjet printer may be used as the printer 113.

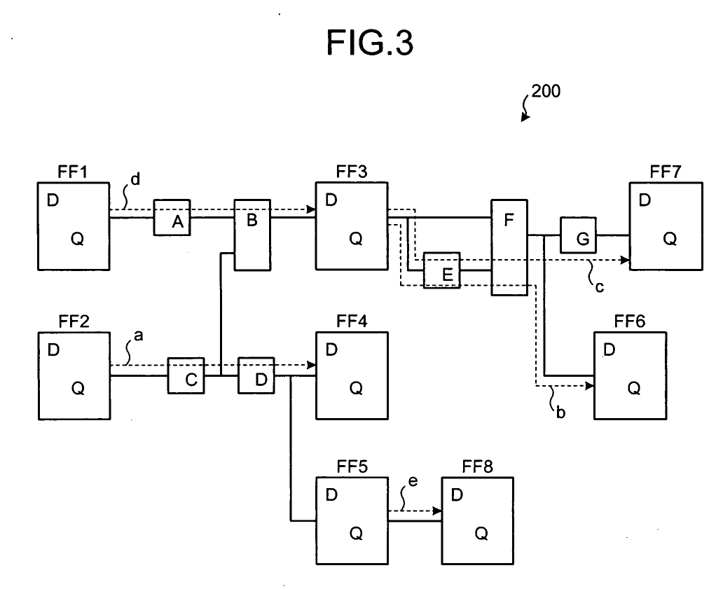

FIG. 3 is a circuit diagram of a target circuit to be tested. As shown in FIG. 3, a target circuit 200 is formed by connecting plural cells, that is, FF cells (FF1 to FF8) and combination cells A to G. The FF1 to FF8 in the target circuit 200 are controlled by the same external clock.

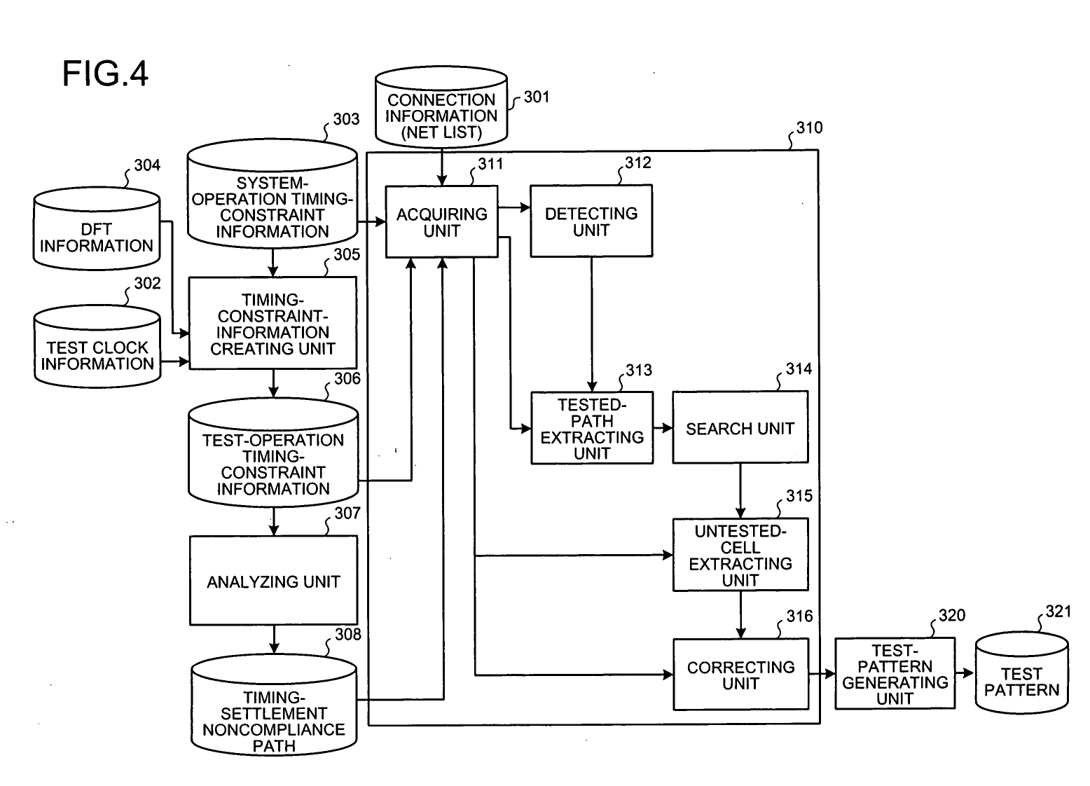

FIG. 4 is a block diagram of the functional configuration of the test pattern generation support apparatus. Connection information 301 shown in FIG. 4 is a net list of the tested circuit shown in FIG. 3. Test clock information 302 includes information on test clock timing, terminals, and frequency.

System-operation timing-constraint information 303 of the target circuit 200 set in the SDC format is information on timing constraint for a system operation. The System-operation timing-constraint information 303 includes a multi-cycle path and a false path of the target circuit 200. DFT information 304 specifies a test terminal, a test clock, and a domain boundary in the target circuit 200.

A timing-constraint-information creating unit 305 determines a clock for driving a path in the system-operation timing-constraint information 303 at a time of test operation based on the test clock information 302, the system-operation timing-constraint information 303, and the DFT information 304. If the clock is not the same as that at a time of system operation, the timing-constraint-information creating unit 305 performs processing for invalidating the path and creates test-operation timing-constraint information 306. The test-operation timing-constraint information 306 also includes the multi-cycle path and the false path of the target circuit 200.

An analyzing unit 307 is a static timing analyzer, and when the system-operation timing-constraint information 303 and the test-operation timing-constraint information 306 are the same, outputs the system-operation timing-constraint information 303 to an apparatus for supporting test pattern generation 310. On the other hand, when the system-operation timing-constraint information 303 is different from the test-operation timing-constraint information 306, the analyzing unit 307 outputs the test-operation timing-constraint information 306 to the apparatus 310. Furthermore, when a timing error cannot be settled by layout correction after the analysis by the analyzing unit 307, the analyzing unit 307 outputs a timing-settlement noncompliance path 308 to the apparatus 310.

The apparatus 310 includes an acquiring unit 311, a detecting unit 312, a tested-path extracting unit 313, a search unit 314, an untested-cell extracting unit 315, and a correcting unit 316. The acquiring unit 311 acquires the connection information 301 of the target circuit 200, and an untested path. The untested path denotes the timing constraint information 303 (or 306) or the timing-settlement noncompliance path 308. An example of the timing constraint information 303 (or 306) in the target circuit 200 is shown in (a) to (d) below.
a) set_false_path-from FF2/Q-to FF4/D
b) set_false_path-from FF3/Q-through E-to FF6/D
c) set_false_path-from FF3/Q-through E-to FF7/D
c) set_multicycle_path 2-from FF1/Q-to FF3/D

Furthermore, an example of the timing-settlement noncompliance path 308 in which timing cannot be settled in the target circuit 200 is shown in (e) below.
e) FF5/Q_FF8/D

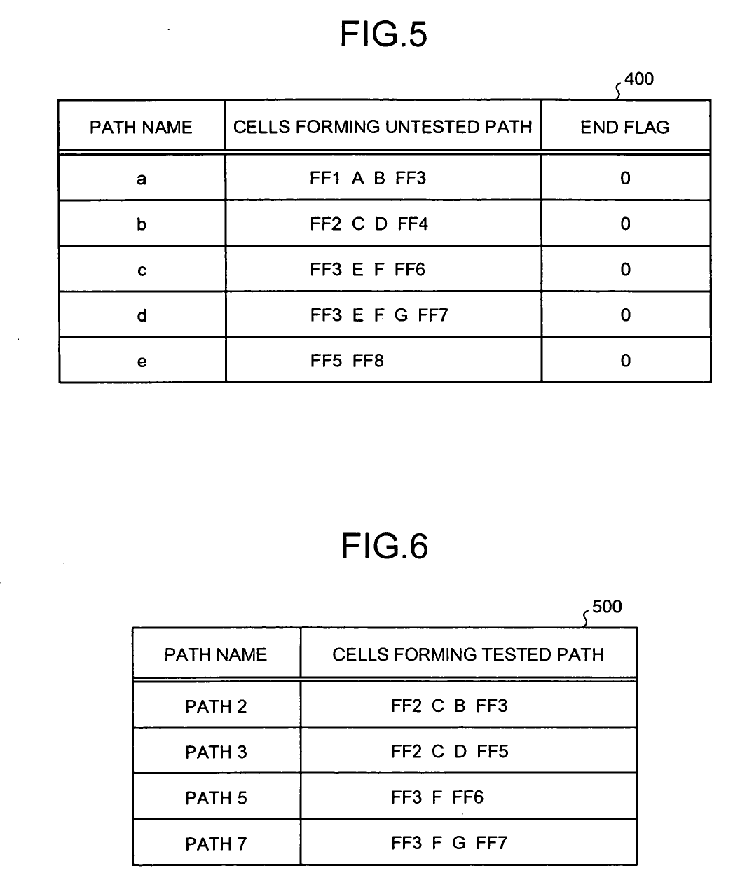

(a) to (e) correspond to respective signs of dotted lines with arrow in FIG. 3. The tested path list is created from untested paths “a” to “e” acquired by the acquiring unit 311. FIG. 5 is a table of an untested path list 400. As shown in FIG. 5, cells forming the path are listed for each of the untested paths “a” to “e” in the untested path list 400. End flags of all of the untested paths “a” to “e” are set to be “0” at this stage.

The detecting unit 312 detects all paths between FF cells in the target circuit 200 based on the connection information 301 acquired. The paths between all the FF cells are as follows.
Path 1: FF1-A-B-FF3
Path 2: FF2-C-B-FF3
Path 3: FF2-C-D-FF4
Path 4: FF2-C-D-FF5
Path 5: FF3-F-FF6
Path 6: FF3-E-F-FF6
Path 7: FF3-F-G-FF7
Path 8: FF3-E-F-G-FF7
Path 9: FF5-FF8

The tested-path extracting unit 313 extracts the tested path from path 1 to path 9 detected by the detecting unit 312 based on the untested paths “a” to “e”. Specifically, paths (path 2, path 3, path 5, path 7) excluding the untested paths “a” to “e” are extracted as the tested path from path 1 to path 9 between the FF cells. The tested-path extracting unit 313 creates a tested path list 500 from the extracted tested paths. FIG. 6 is a table of the tested path list 500. In the tested path list 500, cells forming a path are listed for each of the tested paths (path 2, path 3, path 5, and path 7).

As shown in FIG. 4, the search unit 314 searches the number of paths, in which the respective cells in the target circuit 200 are respectively included in the untested path and the tested path. Specifically, the search unit 314 performs search processing by referring to the untested path list 400 and the tested path list 500. When referring to the untested path list 400 shown in FIG. 5, the search unit 314 refers to only the path for which the end flag is set to “0”. That is, the search unit 314 executes search processing until all of the end flags are changed to “1”.

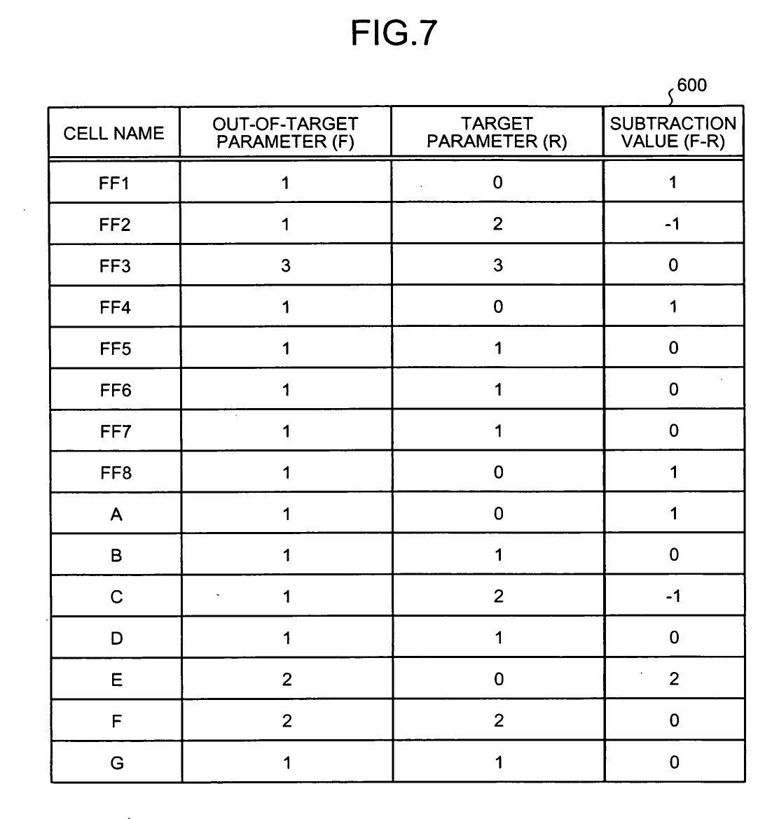

The search processing will be specifically explained. FIG. 7 is a table of a search-result list 600 indicating a result of search by the search unit 314. In the search-result list 600, the number (hereinafter, “out-of-target parameter F”) of cell included in the untested paths “a” to “e” and the number (hereinafter, “target parameter R”) of cell included in the tested path (path 2, path 3, path 5, and path 7) are shown, for each cell in the target circuit 200.

A subtraction value (F−R) obtained by subtracting the target parameter R from the out-of-target parameter F is calculated for each cell in the target circuit 200. When the subtraction value is larger than “0”, the number included in the untested path is larger than the number included in the tested path, and when the subtraction value is smaller than “0”, the number included in the untested path is smaller than the number included in the tested path.

For example, when referring to the table shown in FIG. 5, since FF2 is included only in path b, that is, included only in one untested path, the out-of-target parameter is “1”. Likewise, when referring to the table shown in FIG. 6, since FF2 is included in two tested paths, path 2 and path 3, the target parameter is “2”, and the subtraction value (F−R) is “−1”.

The untested-cell extracting unit 315 extracts an untested cell from among cells forming the target circuit 200 based on the cells forming the untested paths “a” to “e” (see FIG. 5) and the cells forming the tested path (path 2, path 3, path 5, and path 7) (see FIG. 6) extracted by the tested-path extracting unit 313. Specifically, as shown in FIG. 7, the cell having the largest subtraction value among the subtraction values (F−R) for each cell is extracted as the untested cell. When there is more than one cell having the same subtraction value (F−R), a cell is selected based on the following conditions. That is, select one having a smaller target parameter. When the target parameter of the combination cell (A to G) and the target parameter of the FF cell are the same, select the combination cell (A to G). In the table shown in FIG. 7, the cell E is extracted as the untested cell.

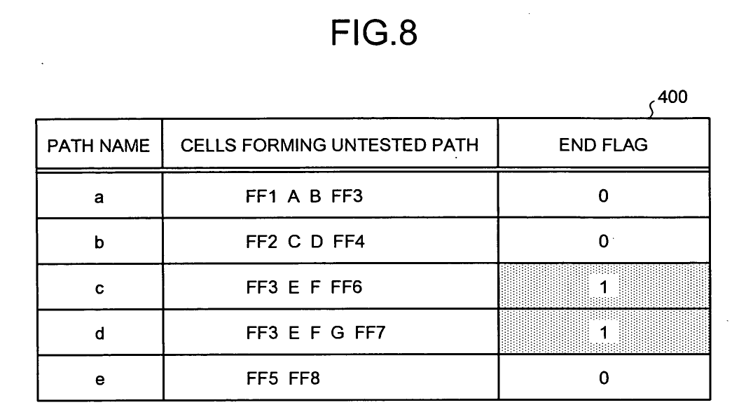

When having extracted the untested cell, the untested-cell extracting unit 315 changes the end flag (see FIG. 5) of the untested path including the untested cell extracted to “1”. In this case, since the cell E is extracted as the untested cell, the end flag of the untested paths c and d shown in FIG. 5 including the cell E is changed to “1”. FIG. 8 is a table of the untested path list 400 changing the end flag.

Thereafter, the search unit 314 refers to the untested path list 400 shown in FIG. 8 to perform search processing. As shown in FIG. 8, since the search unit 314 cannot refer to the paths “c” and “d” in which the end flag is changed to “1”, values of the out-of-target parameter F, the target parameter R, and the subtraction value (F−R) shown in FIG. 7 are also changed.

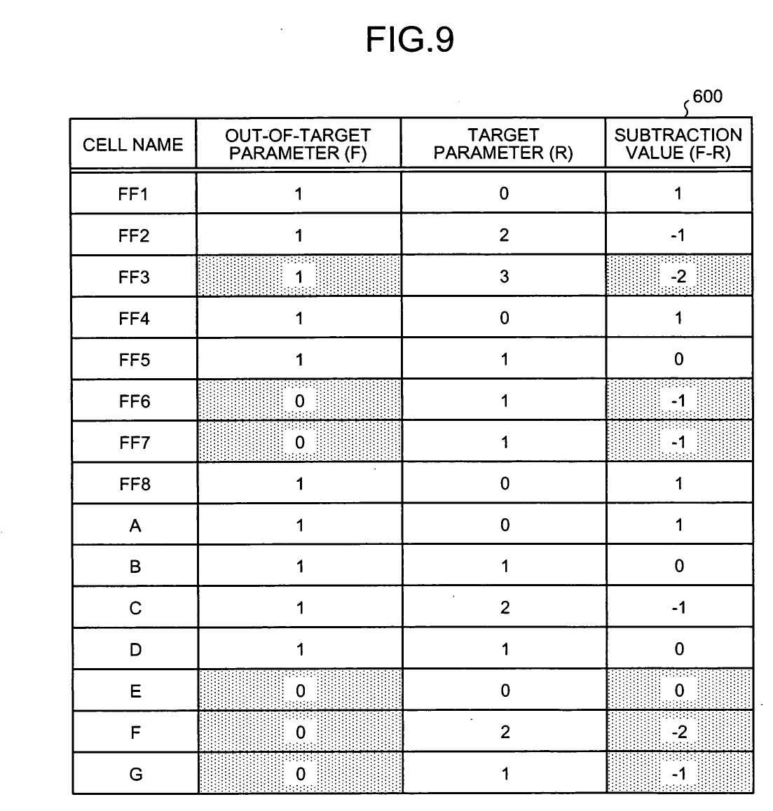

FIG. 9 is a table of a search-result list 900 after changing the end flag shown in FIG. 8 by the search unit 314. In the search-result list 600 shown in FIG. 9, a shaded portion indicates a part in which a change is made. The untested-cell extracting unit 315 extracts the cell having the largest subtraction value from the subtraction values shown in FIG. 9 as the untested cell. In this case, FF1, FF4, FF8, and cell A having the subtraction value “1” are candidates of the untested cell. Based on the conditions above, the cell A is selected to be extracted as the untested cell.

Thereafter, the untested-cell extracting unit 315 changes the end flag (see FIG. 8) of the untested paths including the cell A to “1”. The search unit 314 and the untested-cell extracting unit 315 repeat processing until all end flags become “1”. The untested cells finally obtained are cells E, A, FF4, and FF8.

The correcting unit 316 corrects the connection information 301 so that a dummy buffer is inserted in a stage previous to the untested cells (cell E, cell A, FF4, and FF8) extracted. Specifically, the dummy buffer is connected to a data pin, which is an input terminal of FF4 and FF8, of the untested cells (cell E, cell A, FF4, and FF8).

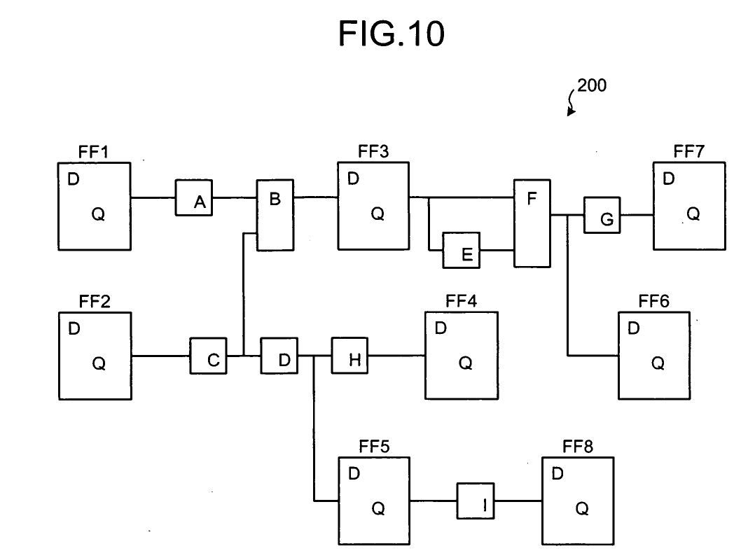

FIG. 10 is a circuit diagram of the target circuit 200 in which the dummy buffer is inserted. In FIG. 10, a dummy buffer H is connected to the data pin of FF4, and a dummy buffer I is connected to the data pin of FF8. A test-pattern generating unit 320 shown in FIG. 4 generates a test pattern 321 by inputting the connection information 301 corrected.

The functions of the timing-constraint-information creating unit 305, the analyzing unit 307, the respective components 311 to 316 in the apparatus 310, and the test-pattern generating unit 320 are realized by the CPU 101 executing a program recorded on a recording medium, such as the ROM 102, the RAM 103, and the HDD 105 shown in FIG. 2, or by the I/F 109.

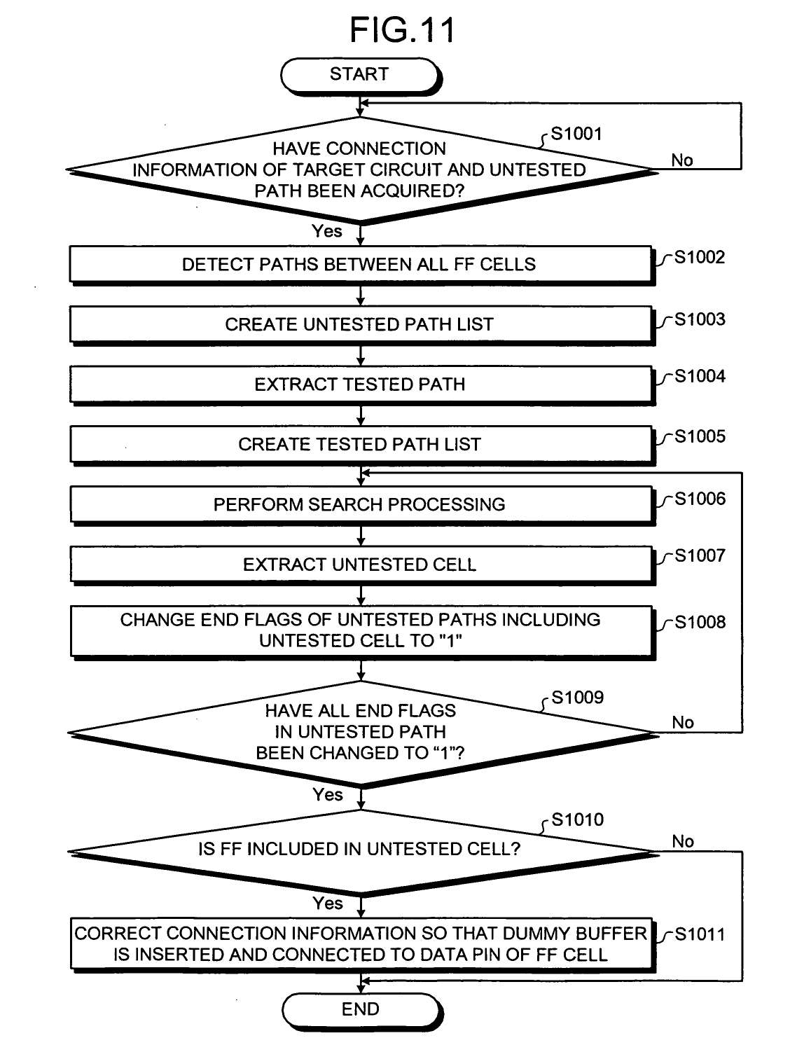

FIG. 11 is a flowchart of a test-pattern-generation supporting process according to the embodiments. As shown in FIG. 11, when the acquiring unit 311 acquires the connection information 301 and the untested paths “a” to “e” (“YES” at step S1001), the detecting unit 312 detects the paths (path 1 to path 9) between all FF cells forming the target circuit 200 (step S1002), and creates the untested path list 400 shown in FIG. 5 (step S1003).

The tested-path extracting unit 313 extracts the tested paths (path 2, path 3, path 5, and path 7) (step S1004), and creates the tested path list 500 shown in FIG. 6 (step S1005). The search unit 314 performs the search processing to create the search-result list 600 shown in FIG. 7 and set the out-of-target parameter F, the target parameter R, and the subtraction value (F−R) for each cell forming the target circuit 200 (step S1006).

The untested-cell extracting unit 315 extracts the untested cell (step S1007), and changes the end flag of the untested path including the extracted untested cell from “0” to “1” (step S1008). When all of the end flags in the untested path list 400 are not changed to “1” (“NO” at step S1009), a process returns to step S1006 to execute the search processing. In this case, since the untested path having the end flag of “1” is not referred to the out-of-target parameter F, the target parameter R, and the subtraction value (F−R) are reset as shown in FIG. 9.

When all end flags in the untested path list 400 are changed to “1” (“YES” at step S1009), it is determined whether an FF cell is included in the extracted untested cell (step S1010). When the FF cell is included (“YES” at step S1010), the connection information 301 is corrected so that a dummy buffer is inserted and connected to the data pin of the FF cell (step S1011). Thus, a series of the process is finished. On the other hand, when no FF cell is included (“NO” at step S1010), the series of processing is finished then.

According to the apparatus 310, a point that is determined as the untested path by mistake, that is, the data pin of the untested cell, can be automatically detected. Accordingly, it is possible to prevent, by inserting the dummy buffer in the point, a problem in which a tested path is detected as an untested path by mistake. Therefore, the detection rate in the transition delay test can be improved.

According to the method and the apparatus 310 for supporting test pattern generation, and the computer product, the TAT can be reduced, and the detection rate in the transition delay test can be improved. Accordingly, an untested path can be provided highly accurately with respect to the test-pattern generating unit 320 (automatic test-pattern generator), thereby improving reliability of the test pattern generated.

The method for supporting test pattern generation that is explained in the embodiments of the present invention is implemented by executing a computer program prepared in advance by a computer, such as a personal computer and a workstation. The computer program is recorded in a computer-readable recording medium, such as the CD-ROM, the MO, and the DVD, and is executed by the computer reading out from the recording medium. The computer program may be a transmission medium that is distributed through a network such as the Internet.

According to the present invention, it is possible to reduce the TAT, and to improve the detection rate in the transition delay test

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. An apparatus for supporting test pattern generation, comprising:
an acquiring unit that acquires connection information and an untested path that is a path not to be tested, the connection information including a netlist of a target circuit to be tested;
a detecting unit that detects all paths between flip-flop cells in the target circuit based on the connection information;
a path extracting unit that extracts a tested path that is a path to be tested, from among the paths detected based on the untested path; and
a cell extracting unit that extracts an untested cell that is not to be tested from among cells in the target circuit, based on cells forming the untested path and cells forming the tested path.

2. The apparatus according to claim 1, wherein the untested path includes a noncompliance path, in which timing is not settled by timing analysis of the target circuit.

3. The apparatus according to claim 1, further comprising a search unit that searches number of cell that is included in the untested path and number of cell that is included in the tested path, wherein
the cell extracting unit extracts the untested cell based on a result of search by the search unit.

4. The apparatus according to claim 1, further comprising a correcting unit that corrects the connection information, so that a dummy buffer is inserted in a stage previous to the untested cell.

5. A method of supporting test pattern generation, comprising:
acquiring connection information and an untested path that is a path not to be tested, the connection information including a netlist of a target circuit to be tested;
detecting all paths between flip-flop cells in the target circuit based on the connection information;
extracting a tested path that is a path to be tested, from among the paths detected based on the untested path; and
extracting an untested cell that is not to be tested from among cells in the target circuit, based on cells forming the untested path and cells forming the tested path.

6. The method according to claim 5, wherein the untested path includes a noncompliance path, in which timing is not settled by timing analysis of the target circuit.

7. The method according to claim 5, further comprising searching number of cell that is included in the untested path and number of cell that is included in the tested path, wherein
the untested cell is extracted based on a result of search at the searching.

8. The method according to claim 5, further comprising correcting the connection information, so that a dummy buffer is inserted in a stage previous to the untested cell.

9. A computer-readable recording medium that stores a computer program for supporting test pattern generation, the computer program making a computer execute:
acquiring connection information and an untested path that is a path not to be tested, the connection information including a netlist of a target circuit to be tested;
detecting all paths between flip-flop cells in the target circuit based on the connection information;
extracting a tested path that is a path to be tested, from among the paths detected based on the untested path; and
extracting an untested cell that is not to be tested from among cells in the target circuit, based on cells forming the untested path and cells forming the tested path.

10. The computer-readable recording medium according to claim 9, wherein the untested path includes a noncompliance path, in which timing is not settled by timing analysis of the target circuit.

11. The computer-readable recording medium according to claim 9, wherein
the computer program further makes the computer execute searching number of cell that is included in the untested path and number of cell that is included in the tested path, and
the untested cell is extracted based on a result of search at the searching.

12. The computer-readable recording medium according to claim 9, wherein
the computer program further makes the computer execute correcting the connection information, so that a dummy buffer is inserted in a stage previous to the untested cell.
